(19) United States
(12) Patent Application Publication
(10) Pub. No.: US 2024/0361706 A1
(43) Pub. Date: Oct. 31, 2024

(54) A POSITION MEASUREMENT SYSTEM, A POSITIONING SYSTEM, A LITHOGRAPHIC APPARATUS, AND A DEVICE MANUFACTURING METHOD

(71) Applicant: ASML Netherlands B.V., Veldhoven (NL)

(72) Inventor: Marcus Adrianus VAN DE KERKHOF, Helmond (NL)

(73) Assignee: ASML Netherlands B.V., Veldhoven (NL)

(21) Appl. No.: 18/577,515

(22) PCT Filed: Jun. 30, 2022
(86) PCT No.: PCT/EP2022/068214

§ 371 Date: Jan. 8, 2024

(30) Foreign Application Priority Data
Jul. 7, 2021 (EP) 21184382.6

(51) Int. Cl. G03F 7/00

(52) U.S. Cl. CPC G03F 7/70775; G03F 7/70725; G03F 7/70758

(57) ABSTRACT

The invention provides a position measurement system to measure a position of an object in a movement direction relative to a reference, said position measurement system comprising: —a diffraction grating, and —an interferometer, wherein the interferometer is configured to direct a measurement beam to the diffraction grating in a measuring direction that is orthogonal to the movement direction of the object, and wherein the diffraction grating is oriented relative to the interferometer such that the measurement beam is substantially at a Littrow angle of the diffraction grating so that a diffracted beam to be received by the interferometer is substantially parallel to the measuring direction.

### CROSS-REFERENCE TO RELATED APPLICATION

The application claims priority of EP application Ser. No. 21/184,382.6 which was filed on 7 Jul. 2021 and which is incorporated herein in its entirety by reference.

### FIELD

The present invention relates to a position measurement system to measure a position of an object in a movement direction relative to a reference. The present invention also relates to a positioning system comprising such a position measurement system. The present invention further relates to a lithographic apparatus comprising such a positioning system and a method for manufacturing a device using such a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Conventional lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

Typically, a lithographic apparatus comprises a positioning system to move and position a substrate table holding the substrate or to move and position a support holding the patterning device. To control the position of the substrate table or support, the position needs to be accurately determined, for instance using interferometers and mirrors. To be able to position all interferometers in substantially the same plane while at the same time being able to measure a position in a direction perpendicular to said plane, the positioning system may make use of a 45 degrees mirror on the substrate table or support and an external reference mirror. However, a drawback of the external reference mirror is that there is a high risk of contamination, for instance due to resist outgassing. This contamination results in risk of focus drifts and requires periodic cleaning, and ultimately replacement of the external reference mirror, which is costly and time-consuming due to the complexity of manufacture.

### SUMMARY

Considering the above, it is an object of the invention to provide a positioning system with the ability to measure an out of plane position with more accuracy and less maintenance.

According to an embodiment of the invention, there is provided a position measurement system to measure a position of an object in a movement direction relative to a reference, said position measurement system comprising:
a diffraction grating, and
an interferometer,
   wherein the interferometer is configured to direct a measurement beam to the diffraction grating in a measuring direction that is orthogonal to the movement direction of the object, and wherein the diffraction grating is oriented relative to the interferometer such that the measurement beam is substantially at a Littrow angle of the diffraction grating so that a diffracted beam to be received by the interferometer is substantially parallel to the measuring direction.

According to another embodiment of the invention, there is provided a positioning system for positioning an object relative to a reference, comprising:
an object actuation system for moving and positioning the object in the moving direction,
a position measurement system for measuring a position of the object, and
a control unit for driving the object actuation system based on an output of the position measurement system and a desired position of the object,
   wherein the position measurement system is a position measurement system according to the invention, and an output of the position measurement system is based on an output of the interferometer.

According to further embodiment of the invention, there is provided a lithographic apparatus comprising a positioning system according to the invention.

According to yet another embodiment of the invention, there is provided a device manufacturing method wherein use is made of a lithographic apparatus according to the invention.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus according to an embodiment of the invention;

FIG. 2 depicts a detailed view of a part of the lithographic apparatus of FIG. 1;

FIG. 3 schematically depicts a position control system as part of a positioning system according to an embodiment of the invention;

FIG. 4 schematically depicts a part of a position measurement system according to an embodiment of the invention;

FIG. 5 schematically depicts a part of a position measurement system according to another embodiment of the invention.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm), but also radiation e.g. used for optical sensors in the range of 400-900 nm.

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

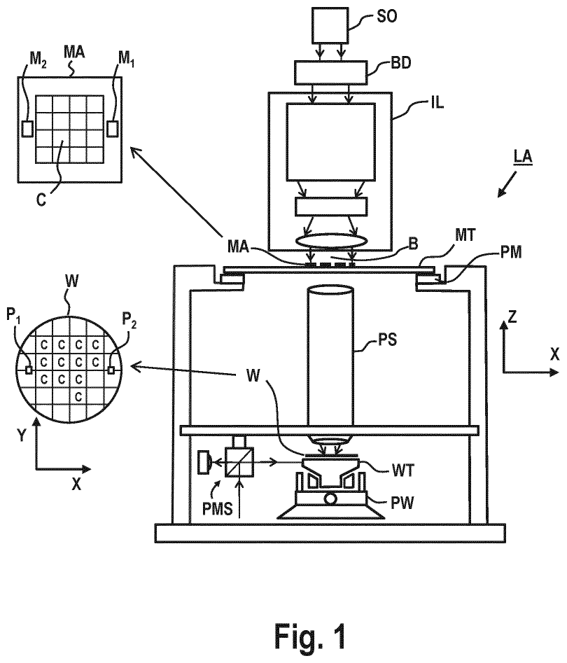

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the patterning device MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C. 5

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

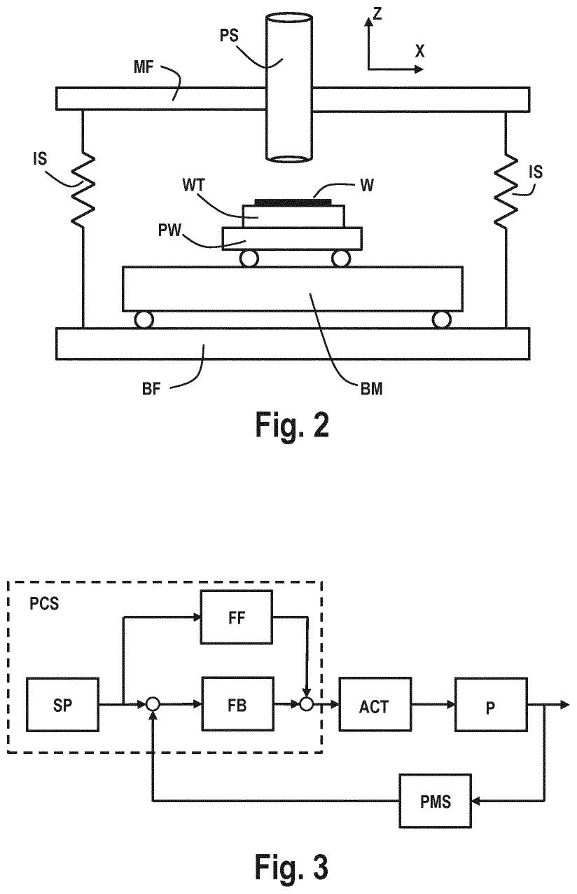

FIG. 2 shows a more detailed view of a part of the lithographic apparatus LA of FIG. 1. The lithographic apparatus LA may be provided with a base frame BF, a balance mass BM, a metrology frame MF and a vibration isolation system IS. The metrology frame MF supports the projection system PS. Additionally, the metrology frame MF may support a part of the position measurement system PMS. The metrology frame MF is supported by the base frame BF via the vibration isolation system IS. The vibration isolation system IS is arranged to prevent or reduce vibrations from propagating from the base frame BF to the metrology frame MF.

The second positioner PW is arranged to accelerate the substrate support WT by providing a driving force between the substrate support WT and the balance mass BM. The driving force accelerates the substrate support WT in a desired direction. Due to the conservation of momentum, the driving force is also applied to the balance mass BM with equal magnitude, but at a direction opposite to the desired direction. Typically, the mass of the balance mass BM is significantly larger than the masses of the moving part of the second positioner PW and the substrate support WT.

In an embodiment, the second positioner PW is supported by the balance mass BM. For example, wherein the second positioner PW comprises a planar motor to levitate the substrate support WT above the balance mass BM. In another embodiment, the second positioner PW is supported by the base frame BF. For example, wherein the second positioner PW comprises a linear motor and wherein the second positioner PW comprises a bearing, like a gas bearing, to levitate the substrate support WT above the base frame BF.

The position measurement system PMS may comprise any type of sensor that is suitable to determine a position of the substrate support WT. The position measurement system PMS may comprise any type of sensor that is suitable to determine a position of the mask support MT. The sensor may be an optical sensor such as an interferometer or an encoder. The position measurement system PMS may comprise a combined system of an interferometer and an encoder. The sensor may be another type of sensor, such as a magnetic sensor, a capacitive sensor or an inductive sensor. The position measurement system PMS may determine the position relative to a reference, for example the metrology frame MF or the projection system PS. The position measurement system PMS may determine the position of the substrate table WT and/or the mask support MT by measuring the position or by measuring a time derivative of the position, such as velocity or acceleration.

The position measurement system PMS may comprise an encoder system. An encoder system is known from for example, United States patent application US2007/0058173A1, filed on Sep. 7, 2006, hereby incorporated by reference. The encoder system comprises an encoder head, a grating and a sensor. The encoder system may receive a primary radiation beam and a secondary radiation beam. Both the primary radiation beam as well as the secondary radiation beam originate from the same radiation beam, i.e., the original radiation beam. At least one of the primary radiation beam and the secondary radiation beam is created by diffracting the original radiation beam with the grating. If both the primary radiation beam and the secondary radiation beam are created by diffracting the original radiation beam with the grating, the primary radiation beam needs to have a different diffraction order than the secondary radiation beam. Different diffraction orders are, for example, +1^{st} order, −1^{st} order, +2^{nd} order and −2^{nd} order. The encoder system optically combines the primary radiation beam and the secondary radiation beam into a combined radiation beam. A sensor in the encoder head determines a phase or phase difference of the combined radiation beam. The sensor generates a signal based on the phase or phase difference. The signal is representative of a position of the encoder head relative to the grating. One of the encoder head and the grating may be arranged on the substrate structure WT. The other of the encoder head and the grating may be arranged on the metrology frame MF or the base frame BF. For example, a plurality of encoder heads is arranged on the metrology frame MF, whereas a grating is arranged on a top surface of the substrate support WT. In another example, a grating is arranged on a bottom surface of the substrate support WT, and an encoder head is arranged below the substrate support WT.

The position measurement system PMS may comprise an interferometer system. An interferometer system is known from, for example, United States patent U.S. Pat. No. 6,020,964, filed on Jul. 13, 1998, hereby incorporated by reference. The interferometer system may comprise a beam splitter, a mirror, a reference mirror and a sensor. A beam of radiation is split by the beam splitter into a reference beam and a measurement beam. The measurement beam propagates to the mirror and is reflected by the mirror back to the beam splitter. The reference beam propagates to the reference mirror and is reflected by the reference mirror back to the beam splitter. At the beam splitter, the measurement beam and the reference beam are combined into a combined radiation beam. The combined radiation beam is incident on the sensor. The sensor determines a phase or a frequency of the combined radiation beam. The sensor generates a signal based on the phase or the frequency. The signal is representative of a displacement of the mirror. In an embodiment, the mirror is connected to the substrate support WT. The reference mirror may be connected to the metrology frame MF. In an embodiment, the measurement beam and the reference beam are combined into a combined radiation beam by an additional optical component instead of the beam splitter.

The first positioner PM may comprise a long-stroke module and a short-stroke module. The short-stroke module is arranged to move the mask support MT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the first positioner PM is able to move the mask support MT relative to the projection system PS with a high accuracy over a large range of movement. Similarly, the second positioner PW may comprise a long-stroke module and a short-stroke module. The short-stroke module is arranged to move the substrate support WT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the second positioner PW is able to move the substrate support WT relative to the projection system PS with a high accuracy over a large range of movement.

The first positioner PM and the second positioner PW each are provided with an actuator to move respectively the mask support MT and the substrate support WT. The actuator may be a linear actuator to provide a driving force along a single axis, for example the y-axis. Multiple linear actuators may be applied to provide driving forces along multiple axis. The actuator may be a planar actuator to provide a driving force along multiple axis. For example, the planar actuator may be arranged to move the substrate support WT in 6 degrees of freedom. The actuator may be an electromagnetic actuator comprising at least one coil and at least one magnet. The actuator is arranged to move the at least one coil relative to the at least one magnet by applying an electrical current to the at least one coil. The actuator may be a moving-magnet type actuator, which has the at least one magnet coupled to the substrate support WT respectively to the mask support MT. The actuator may be a moving-coil type actuator which has the at least one coil coupled to the substrate support WT respectively to the mask support MT. The actuator may be a voice-coil actuator, a reluctance actuator, a Lorentz-actuator or a piezo-actuator, or any other suitable actuator.

The lithographic apparatus LA comprises a position control system PCS as schematically depicted in FIG. 3. The position control system PCS comprises a setpoint generator SP, a feedforward controller FF and a feedback controller FB. The position control system PCS provides a drive signal to the actuator ACT. The actuator ACT may be the actuator of the first positioner PM or the second positioner PW. The actuator ACT drives the plant P, which may comprise the substrate support WT or the mask support MT. An output of the plant P is a position quantity such as position or velocity or acceleration. The position quantity is measured with the position measurement system PMS. The position measurement system PMS generates a signal, which is a position signal representative of the position quantity of the plant P. The setpoint generator SP generates a signal, which is a reference signal representative of a desired position quantity of the plant P. For example, the reference signal represents a desired trajectory of the substrate support WT. A difference between the reference signal and the position signal forms an input for the feedback controller FB. Based on the input, the feedback controller FB provides at least part of the drive signal for the actuator ACT. The reference signal may form an input for the feedforward controller FF. Based on the input, the feedforward controller FF provides at least part of the drive signal for the actuator ACT. The feedforward FF may make use of information about dynamical characteristics of the plant P, such as mass, stiffness, resonance modes and eigenfrequencies.

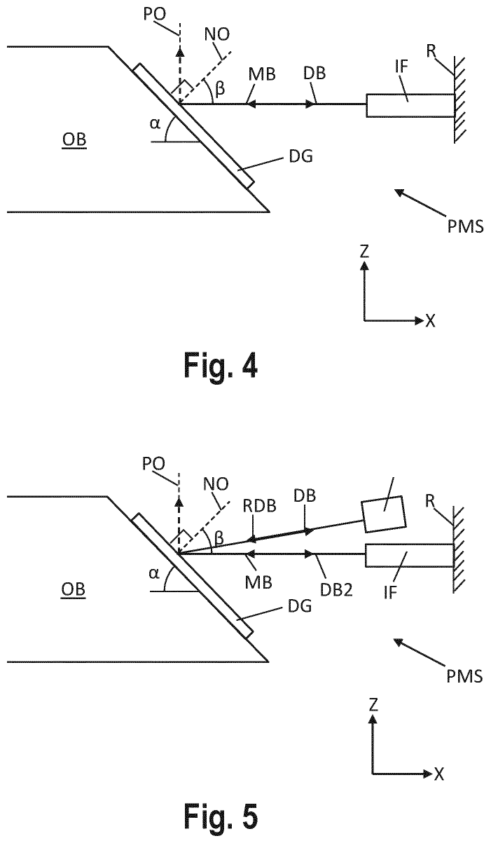

FIG. 4 schematically depicts a part of a position measurement system PMS according to an embodiment of the invention for measuring a position of an object OB relative to a reference R. The object OB may for instance be the substrate table configured to hold a substrate or a support configured to hold a patterning device. The reference R may be a measurement frame or a projection system.

The position measurement system PMS comprises a diffraction grating DG cooperating with an interferometer IF. In this embodiment, the object OB is provided with the diffraction grating DG and the interferometer IF is arranged on the reference R, but it is also envisaged that this may be the other way around, i.e. the object OB may be provided with the interferometer IF and the diffraction grating DG may be arranged on the reference R.

The object OB is moveable in a movement direction, which in this example corresponds to the Z-direction.

The diffraction grating DG is oriented such that it makes an angle α with the X-direction. The interferometer IF is arranged such that it is able to direct a measurement beam MB to the diffraction grating in a measuring direction that is parallel to the X-direction. A portion PO of the measurement beam MB will reflect off the diffraction grating DG and travel in the Z-direction when α=45 degrees. However, this portion PO is not used by the position measurement system. The measurement beam MB is directed to the diffraction grating DG at an angle β to a normal NO of the diffraction grating DG, where α+β=90 degrees. The diffraction grating DG is oriented relative to the interferometer IF such that the measurement beam MB is substantially at a Littrow angle of the diffraction grating DG, meaning that for the specific wavelength of the measurement beam output by the interferometer IF, one of the diffraction angles of the diffraction grating DG is substantially β, so that a diffracted beam DB to be received by the interferometer IF is substantially parallel to the measuring direction. This may be the first order diffracted beam, which may have the highest intensity of the diffracted beams, but may also be a higher order diffracted beam. The received diffracted beam can then be used by the interferometer IF to determine a position of the object OB in the movement direction.

FIG. 5 schematically depicts a part of a position measurement system PMS according to another embodiment of the invention for measuring a position of an object OB relative to a reference R. The embodiment of FIG. 5 is very similar to the embodiment of FIG. 4, so that only the differences will be described in detail here.

The main difference between the two embodiments of FIGS. 4 and 5 is that the diffracted beam DB is not received directly by the interferometer IF, but is directed to an optical element OE, e.g. a retro-reflector, to reflect the diffracted beam back to the diffraction grating DG. The reflected diffracted beam is indicated in FIG. 5 using the reference symbol RDB. The reflected diffracted beam RDB will be diffracted again by the diffraction grating DG resulting in a second diffracted beam DB2 that is to be received by the interferometer IF for processing. The measurement beam MB is thus diffracted twice by the diffraction grating DG, which may be referred to as a double-pass configuration making the position measurement system more robust against a rotation about an axis parallel to the Z-direction (yaw) and a rotation about an axis parallel to the X-direction or the Y-direction perpendicular to both the X-direction and the Y-direction (tilt).

The main advantages of the position measurement system according to the invention is that the external reference mirror is no longer required and thus there is no sensitivity to contamination of this mirror or any other drifts of the external reference mirror. Additionally, with no external reference mirror, more space is made available for other system components, or for a more compact arrangement.

The diffraction grating DG may be a phase grating or an amplitude grating or a combination thereof. The diffraction grating DG may further be a blazed grating optimizing the optical power in the diffracted beam.

When the object OB in the embodiments of FIGS. 4 and 5 can move in the movement direction, i.e. the Z-direction, and not in the measuring direction, i.e. the X-direction, the output of the interferometer is representative for the position in the movement direction and can be used to determine displacement in the movement direction directly. However, when the object OB is also moveable in the measuring direction, i.e. the X-direction, the output of the interferometer is representative for the position in the movement direction and the position in the measuring direction and it is then no longer possible to distinguish between a displacement in the movement direction and a displacement in the measuring direction of the object. To this end, the position measurement system may be equipped with a sensor to measure a position of the object in the measuring direction allowing the output of the sensor to be combined with the output of the interferometer to be able to distinguish between a displacement in the measuring direction and a displacement in the movement direction perpendicular to the measuring direction. This sensor may be another interferometer using a flat mirror on the object.

Although the embodiments shown have an angle α=β=45 degrees, it is apparent that any angle can be chosen, e.g. an angle in the range of 30-60 degrees.

Although not necessary per se, it is preferred that the moving range in the movement direction is smaller than a moving range in any other direction perpendicular to the movement direction. For instance, the moving range in the X-direction and the Y-direction may be much larger than the moving range in the Z-direction. An advantage of the position measurement system according to the invention is that the measurement beam is directed in a plane parallel to the X-Y plane and the diffraction grating DG can be kept relatively small. A measurement beam that is non-perpendicular to the movement direction would require a relatively large diffraction grating. Hence, the advantage of the omission of the external reference mirror would then be counteracted by the requirement of a large diffraction grating.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set out as in the following numbered clauses.
1. A position measurement system to measure a position of an object in a movement direction relative to a reference, said position measurement system comprising:
   a diffraction grating, and
   an interferometer,
   wherein the interferometer is configured to direct a measurement beam to the diffraction grating in a measuring direction that is orthogonal to the movement direction of the object, and wherein the diffraction grating is oriented relative to the interferometer such that the measurement beam is substantially at a Littrow angle of the diffraction grating so that a diffracted beam to be received by the interferometer is substantially parallel to the measuring direction.
2. A position measurement system according to clause 1, wherein the diffraction grating is oriented at an angle between 30-60 degrees, e.g. 45 degrees, relative to the measuring direction, which angle corresponds to the Littrow angle of the diffraction grating.
3. A position measurement system according to clause 1 or 2, further comprising an optical element configured to reflect the diffracted beam back to the diffraction grating in the measuring direction for a further diffraction before being received by the interferometer.
4. A position measurement system according to any of clauses 1-3, wherein the diffraction grating is a phase grating.
5. A position measurement system according to any of clauses 1-4, wherein the diffraction grating is an amplitude grating.
6. A position measurement system according to any of clauses 1-5, wherein the diffraction grating is a blazed grating manufactured in a Littrow configuration corresponding to the Littrow angle.
7. A positioning system for positioning an object relative to a reference, comprising:
   an object actuation system for moving and positioning the object in the moving direction,
   a position measurement system for measuring a position of the object, and
   a control unit for driving the object actuation system based on an output of the position measurement system and a desired position of the object,
   wherein the position measurement system is a position measurement system according to any of clauses 1-6, and an output of the position measurement system is based on an output of the interferometer.
8. A positioning system according to clause 7, wherein the diffraction grating is arranged on the object, and wherein the interferometer is arranged on the reference.
9. A positioning system according to clause 7 or 8, wherein the object actuation system is configured to move and position the object in the measuring direction, wherein the position measurement system comprises a sensor for measuring a position of the object in the measuring direction, and wherein the position measurement system or the control unit is configured to determine a position of the object in the movement direction based on an output of the interferometer and on an output of the sensor.
10. A lithographic apparatus comprising a positioning system according to any of clauses 7-9.
11. A lithographic apparatus according to clause 10, further comprising:
   an illumination system configured to condition a radiation beam;
   a support constructed to support a patterning device, the patterning device being capable of imparting the radiation with a pattern in its cross-section to form a patterned radiation beam;
   a substrate table constructed to hold a substrate; and
   a projection system configured to project the patterned radiation beam onto a target portion of the substrate,
   wherein the object is the substrate table.
12. A lithographic apparatus according to clause 10, further comprising:
   an illumination system configured to condition a radiation beam;
   a support constructed to support a patterning device, the patterning device being capable of imparting the radiation with a pattern in its cross-section to form a patterned radiation beam;
   a substrate table constructed to hold a substrate; and
   a projection system configured to project the patterned radiation beam onto a target portion of the substrate,
   wherein the object is the support.
13. A device manufacturing method wherein use is made of a lithographic apparatus according to any of clauses 10-12.

1.-13. (canceled)

14. A position measurement system comprising:
a diffraction grating; and
an interferometer, and
wherein the interferometer is configured to direct a measurement beam to the diffraction grating in a measuring direction that is orthogonal to a movement direction of an object, and
wherein the diffraction grating is oriented relative to the interferometer such that the measurement beam is substantially at a Littrow angle of the diffraction grating so that a diffracted beam to be received by the interferometer is substantially parallel to the measuring direction.

15. The position measurement system of claim 14, wherein the diffraction grating is oriented at an angle between 30-60 degrees and/or 45 degrees relative to the measuring direction, which angle corresponds to the Littrow angle of the diffraction grating.

16. The position measurement system of claim 14, further comprising an optical element configured to reflect the diffracted beam back to the diffraction grating in the measuring direction for a further diffraction of the diffracted beam before it is received by the interferometer.

17. The position measurement system of claim 14, wherein the diffraction grating is a phase grating.

18. The position measurement system claim 14, wherein the diffraction grating is an amplitude grating.

19. The position measurement system of claim 14, wherein the diffraction grating is a blazed grating manufactured in a Littrow configuration corresponding to the Littrow angle.

20. A positioning system comprising:
an object actuation system configured to move and position an object in a moving direction;
a position measurement system configured to measure a position of the object, the position measurement system comprising:
a diffraction grating, and
an interferometer, and
wherein the interferometer is configured to direct a measurement beam to the diffraction grating in a measuring direction that is orthogonal to a movement direction of an object,
wherein the diffraction grating is oriented relative to the interferometer such that the measurement beam is substantially at a Littrow angle of the diffraction grating so that a diffracted beam to be received by the interferometer is substantially parallel to the measuring direction,
wherein an output of the position measurement system is based on an output of the interferometer; and
a control unit configured to drive the object actuation system based on an output of the position measurement system and a desired position of the object.

21. The positioning system according to claim 20, wherein:
the diffraction grating is arranged on the object, and
the interferometer is arranged on a reference object.

22. The positioning system according to claim 20, wherein:
the object actuation system is configured to move and position the object in the measuring direction,
the position measurement system further comprises a sensor configured to measure a position of the object in the measuring direction, and
the position measurement system or the control unit is configured to determine a position of the object in the movement direction based on an output of the interferometer and on an output of the sensor.

23. A lithographic apparatus comprising a positioning system of claim 20.

24. The lithographic apparatus of claim 23, further comprising:
an illumination system configured to condition a radiation beam;
a support constructed to support a patterning device, the patterning device being capable of imparting the radiation with a pattern in its cross-section to form a patterned radiation beam;
a substrate table constructed to hold a substrate; and
a projection system configured to project the patterned radiation beam onto a target portion of the substrate,
wherein the object is the substrate table.

25. The lithographic apparatus of claim 23, further comprising:
an illumination system configured to condition a radiation beam;
a support constructed to support a patterning device, the patterning device being capable of imparting the radiation with a pattern in its cross-section to form a patterned radiation beam;
a substrate table constructed to hold a substrate; and
a projection system configured to project the patterned radiation beam onto a target portion of the substrate,
wherein the object is the support.

26. A device manufacturing method wherein use is made of a lithographic apparatus of claim 23.
